(19) United States
(12) Patent Application Publication
(10) Pub. No.: US 2024/0290780 A1
(43) Pub. Date: Aug. 29, 2024

(54) SEMICONDUCTOR STRUCTURE

(71) Applicant: MEDIATEK INC., Hsinchu City (TW)

(72) Inventors: Zheng ZENG, Hsinchu City (TW); Chia-Hsin HU, Hsinchu City (TW); Chen-Ting LENG, Hsinchu City (TW)

(21) Appl. No.: 18/413,264

(22) Filed: Jan. 16, 2024

Related U.S. Application Data
(60) Provisional application No. 63/486,487, filed on Feb. 23, 2023.

(51) Int. Cl. H01L 27/06; H01L 23/528; H01L 29/06; H01L 29/417; H01L 29/423; H01L 29/775; H01L 29/94

(52) U.S. Cl. CPC H01L 27/0629; H01L 23/5286; H01L 29/0673; H01L 29/41733; H01L 29/42392; H01L 29/775; H01L 29/94

(57) ABSTRACT

A semiconductor structure is provided. The semiconductor structure includes a semiconductor substrate, first and second well regions, first and second gate-all-around (GAA) field-effect transistor devices and a first dielectric layer. The first and second well regions are arranged in the semiconductor substrate and separated from each other. Top and bottom surfaces of the first and second well regions are aligned with top and bottom surfaces of the semiconductor substrate. The first and second GAA field-effect transistor devices are formed over the first and second well regions. A first gate structure of the first GAA field-effect transistor device is electrically connected to a power supply terminal. The first epitaxial source/drain features of the first GAA field-effect transistor are electrically connected to the second gate structure of the second GAA field-effect transistor. The second epitaxial source/drain features of the second GAA field-effect transistor are electrically connected to a ground terminal.

### CROSS REFERENCE TO RELATED APPLICATIONS

This application claims the benefit of U.S. Provisional Application No. 63/486,487, filed Feb. 23, 2023, the entirety of which is incorporated by reference herein.

### BACKGROUND OF THE INVENTION

### Field of the Invention

The present invention relates to a semiconductor structure and, in particular, to a capacitor fabricated by gate-all-around (GAA) processes.

### Description of the Related Art

In recent years, advanced integrated circuit (IC) devices have become increasingly multifunctional and have been scaled down in terms of size. Although the scaling-down process generally increases production efficiency and lowers the associated costs, it has also increased the complexity of processing and manufacturing IC devices. For example, Fin Field-Effect Transistor devices (FinFETs) have been introduced to replace planar transistor devices. Among these FinFETs, gate-all-around (GAA) structures such as nanosheet metal-oxide-semiconductor field-effect transistor devices (MOSFET) with excellent electrical characteristics have been developed. These characteristics include improved power performance and better area-scaling than what is available using current FinFET technologies.

Although existing semiconductor structures including nanosheet transistor devices and methods for manufacturing the same have been adequate for their intended purposes, they have not been entirely satisfactory in all respects. For example, it is a challenge to fabricate devices for high-voltage applications using the low-voltage gate-all-around (GAA) processes.

Thus, a novel semiconductor structure is desirable to improve the withstand voltage of the device.

### BRIEF SUMMARY OF THE INVENTION

An embodiment of the present invention provides a semiconductor structure. The semiconductor structure includes a semiconductor substrate, a first well region, a second well region, a first gate-all-around (GAA) field-effect transistor device, a second gate-all-around (GAA) field-effect transistor device and a first dielectric layer. The semiconductor substrate has a top surface and a bottom surface. The first well region and the second well region are arranged in the semiconductor substrate and separated from each other. Top and bottom surfaces of the first and second well regions are aligned with the top and bottom surfaces of the semiconductor substrate. The first gate-all-around (GAA) field-effect transistor device is formed over the first well region. The first GAA field-effect transistor device includes a first gate structure and first epitaxial source/drain features disposed on opposite sides of the first gate structure. The second gate-all-around (GAA) field-effect transistor device is formed over the second well region. The second GAA field-effect transistor device includes a second gate structure and second epitaxial source/drain features disposed on opposite sides of the second gate structure. The first gate structure is electrically connected to a power supply terminal. The first epitaxial source/drain features are electrically connected to the second gate structure. The second epitaxial source/drain features are electrically connected to a ground terminal.

In some embodiments, the first epitaxial source/drain features are electrically connected to each other. In some embodiments, the second epitaxial source/drain features are electrically connected to each other. In some embodiments, the semiconductor structure further includes a first dielectric layer covering the first and second gate structures. The first gate structure and the first epitaxial source/drain features and a first portion of the first dielectric layer between the first gate structure and first epitaxial source/drain features form a first capacitor. In some embodiments, the second gate structure and the second epitaxial source/drain features and a second portion of the first dielectric layer between the second gate structure and second epitaxial source/drain features form a second capacitor. In some embodiments, the first capacitor and the second capacitor are connected in series. In some embodiments, the semiconductor structure further includes a second dielectric layer, a first front-side gate contact and first front-side source/drain contacts. The second dielectric layer covers the first and second GAA field-effect transistor devices. The first front-side gate contact passes through the second dielectric layer and is electrically connected to the first gate structure. First front-side source/drain contacts pass through the second dielectric layer and are electrically connected to the first epitaxial source/drain features. In some embodiments, the semiconductor structure further includes a second front-side gate contact and second front-side source/drain contacts. The second front-side gate contact passes through the second dielectric layer and is electrically connected to the second gate structure. Second front-side source/drain contacts pass through the second dielectric layer and are electrically connected to the second epitaxial source/drain features. In some embodiments, the semiconductor substrate is electrically floating. In some embodiments, the first and second source/drain epitaxial features have a first conductivity type, and wherein the first and second well regions have a second conductivity type that is different from the first conductivity type. In some embodiments, the semiconductor substrate has the first conductivity type.

In some embodiments, the semiconductor structure further includes a third well region, a third gate-all-around (GAA) field-effect transistor device and a third back-side gate contact. The third well region is arranged in the semiconductor substrate, wherein top and bottom surfaces of the third well region are aligned with the top and bottom surfaces of the substrate. The third gate-all-around (GAA) field-effect transistor device is formed over the third well region. The third GAA field-effect transistor device includes a third gate structure and third epitaxial source/drain features disposed on opposite sides of the third gate structure. The third back-side gate contact is formed in such a way that it passes through the semiconductor substrate and is electrically connected to the third gate structure. In some embodiments, the semiconductor structure further includes a third back-side source/drain contact formed in such a way that it passes through the semiconductor substrate and is electrically connected to one of the third epitaxial source/drain features. In some embodiments, the third epitaxial source/drain features of the third GAA field-effect transistor device is not used as the first epitaxial source/drain features or the second epitaxial source/drain features.

An embodiment of the present invention provides a semiconductor structure. The semiconductor structure includes a semiconductor substrate, a first well region, a second well region, a first gate-all-around (GAA) field-effect transistor device, a second gate-all-around (GAA) field-effect transistor device and a first dielectric layer. The semiconductor substrate has a top surface and a bottom surface. The first well region and the second well region are arranged in the semiconductor substrate and separated from each other. Bottom surfaces of the first and second well regions are exposed from a bottom surface of the semiconductor substrate. The first gate-all-around (GAA) field-effect transistor device is formed over the first well region. The first GAA field-effect transistor device includes a first fin structure and first epitaxial source/drain features. The first fin structure protrudes from the semiconductor substrate. The first fin structure includes first channel layers and a first gate structure that is wrapped around the first channel layer. The first epitaxial source/drain features are connected to opposite sides of the first channel layers. The second gate-all-around (GAA) field-effect transistor device is formed over the second well region. The second GAA field-effect transistor device includes a second fin structure and second epitaxial source/drain features. The second fin structure protrudes from the semiconductor substrate. The second fin structure comprises second channel layers and a second gate structure that is wrapped around the second channel layer. The second epitaxial source/drain features are connected to opposite sides of the second channel layers. The first dielectric layer covers the first and second gate structures. The first epitaxial source/drain features are electrically connected to the second gate structure. The first gate structure and the first epitaxial source/drain features and a first portion of the first dielectric layer between the first gate structure and first epitaxial source/drain features form a first capacitor.

In some embodiments, the first fin structure and the second fin structure are separated from each other. In some embodiments, the second epitaxial source/drain features are electrically connected to each other, and wherein the second gate structure and the second epitaxial source/drain features and a second portion of the first dielectric layer between the second gate structure and second epitaxial source/drain features form a second capacitor. In some embodiments, the first capacitor and the second capacitor are connected in series. In some embodiments, the first gate structure is electrically connected to a power supply terminal, and wherein the second epitaxial source/drain features are electrically connected to a ground terminal. In some embodiments, the semiconductor structure further includes a second dielectric layer, a first front-side gate contact, first front-side source/drain contact, a second front-side gate contact and second front-side source/drain contacts. The first front-side gate contact passes through the second dielectric layer and is electrically connected to the first gate structure of the first GAA field-effect transistor device. The first front-side source/drain contacts pass through the second dielectric layer and is electrically connected to the first epitaxial source/drain features of the first GAA field-effect transistor device. The second front-side gate contact passes through the second dielectric layer and is electrically connected to the second gate structure of the second GAA field-effect transistor device. The second front-side source/drain contacts pass through the second dielectric layer and are electrically connected to the second epitaxial source/drain features of the second GAA field-effect transistor device. In some embodiments, the semiconductor substrate is electrically floating. In some embodiments, the first and second source/drain epitaxial features have a first conductivity type, and wherein the first and second well regions have a second conductivity type that is different from the first conductivity type. In some embodiments, the semiconductor substrate has the first conductivity type.

In some embodiments, the semiconductor structure further includes a third well region, a third gate-all-around (GAA) field-effect transistor device and a third back-side gate contact. The third well region is arranged in the semiconductor substrate, wherein top and bottom surfaces of the third well region are aligned with the top and bottom surfaces of the substrate. The third gate-all-around (GAA) field-effect transistor device is formed over the third well region. The third GAA field-effect transistor device includes a third fin structure and third epitaxial source/drain features. The third fin structure protrudes from the semiconductor substrate. The third fin structure includes third channel layers and a third gate structure that is wrapped around the third channel layer. The third back-side gate contact is formed in such a way that it passes through the semiconductor substrate and is electrically connected to the third gate structure. In some embodiments, the semiconductor structure further includes a third back-side source/drain contact formed in such a way that it passes through the semiconductor substrate and is electrically connected to one of the third epitaxial source/drain features. In some embodiments, the third epitaxial source/drain features of the third GAA field-effect transistor device are not used as the first, second, third or fourth epitaxial source/drain feature.

### BRIEF DESCRIPTION OF THE DRAWINGS

The present invention can be more fully understood by reading the subsequent detailed description and examples with references made to the accompanying drawings, wherein:

FIG. 1 is a top view of a semiconductor structure in accordance with some embodiments of the disclosure;

FIG. 2 is a perspective view of a portion of the semiconductor structure of FIG. 1 in accordance with some embodiments of the disclosure; and

FIG. 3 is a cross-sectional view of a portion of the semiconductor structure along lines X1-X1′, X2-X2′ and X3-X3′ of FIG.1 in accordance with some embodiments of the disclosure.

### DETAILED DESCRIPTION OF THE INVENTION

The following description is made for the purpose of illustrating the general principles of the invention and should not be taken in a limiting sense. The scope of the invention is best determined by reference to the appended claims.

Advanced integrated circuit (IC) devices have become increasingly multifunctional and have been scaled down in size. Although the scaling down process generally increases production efficiency and lowers the associated costs, it has also increased the complexity of processing and manufacturing IC devices. For example, Fin Field-Effect Transistors (FinFETs) have been introduced to replace planar transistors. Among these FinFETs, gate-all-around (GAA) structures such as nanosheet or nanowire metal-oxide-semiconductor field-effect transistors (MOSFET) have been developed to possess excellent electrical characteristics, such as better power performance and area scaling compared to the current FinFET technologies. Furthermore, back-side power technology is used in gate-all-around (GAA) structures to decrease front-side routing, so as to decrease back end of line (BEOL) capacitance and IR drop, thereby improving performance of IC. However, the current gate-all-around (GAA) platform only provides core devices operated in a lower withstand voltage (for example, at the voltage level below about 1.2V), it is a challenge to fabricate capacitors for input/output (IO) devices operated in a higher withstand voltage (for example, at the voltage level between about 1.2 and 2.5V) using the low-voltage gate-all-around (GAA) processes.

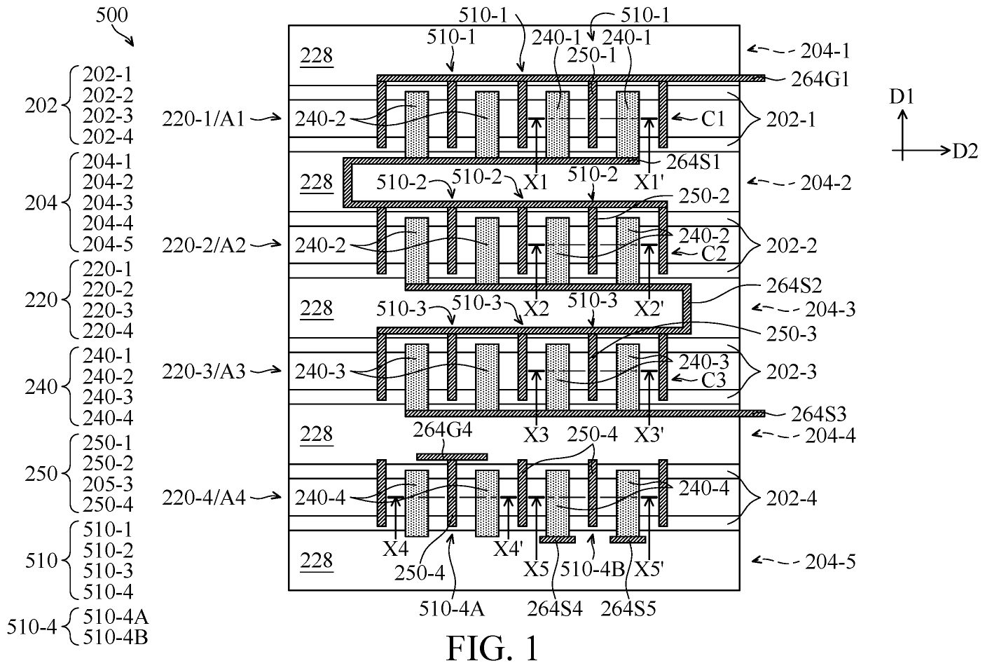

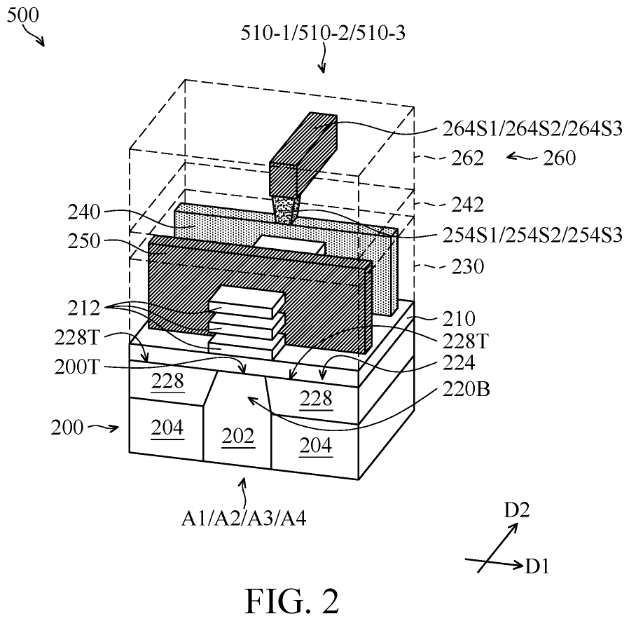

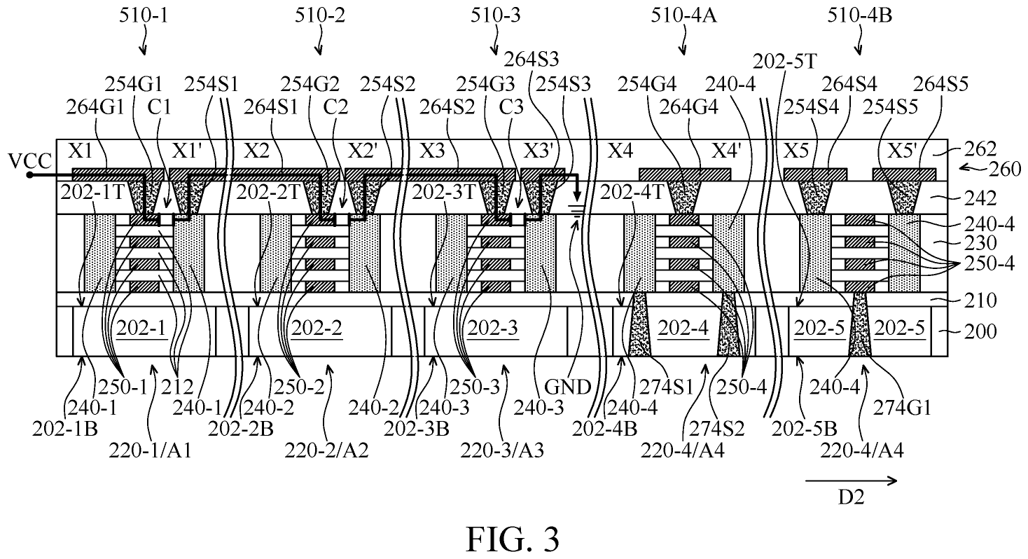

FIG. 1 is a top view of a semiconductor structure 500 in accordance with some embodiments of the disclosure. FIG. 2 is a perspective view of a portion of the semiconductor structure 500 of FIG. 1 in accordance with some embodiments of the disclosure. FIG. 3 is a cross-sectional view of a portion of the semiconductor structure 500 of FIG.1 in accordance with some embodiments of the disclosure. In some embodiments, the semiconductor structure 500 is applied in the back-side power technology and fabricated by the gate-all-around (GAA) processes. For illustration, an insulating layer 210, a dielectric layer 230, an interlayer dielectric (ILD) layer 242 and an intermetal dielectric (IMD) layer 262 (shown in FIGS. 2 and 3) formed over gate-all-around (GAA) field-effect transistor devices 510 (including gate-all-around (GAA) field-effect transistor devices 510-1, 510-2, 510-3 and 510-4) are hidden in FIG. 1. In addition, the dielectric layer 230, the ILD layer 242 and the IMD layer 262 (shown in FIG. 3) may be hidden (drawn in dashed lines) to expose portions of the gate-all-around (GAA) field-effect transistor devices 510-1, 510-2, 510-3 (drawn in solid lines) in FIG. 2.

As shown in FIG. 1, the semiconductor structure 500 includes capacitors C1, C2 and C3 formed from the gate-all-around (GAA) field-effect transistor devices 510-1, 510-2 and 510-3 connected to a front-side interconnect structure and gate-all-around (GAA) field-effect transistor devices 510-4 connected to front-side and back-side interconnect structures. The capacitor C1, C2 and C3 are formed on active regions A1, A2 and A3. In addition, the gate-all-around (GAA) field-effect transistor devices 510-4 are formed on an active region A4. In some embodiments, the active regions A1, A2 and A3 and A4 are separated from each other and provided for the core devices formed thereon.

In some embodiments, the semiconductor structure 500 includes a semiconductor substrate 200, a well regions 202 (including well regions 202-1, 202-2, 202-3 and 202-4), a well region 204 (including well regions 204-1, 204-2, 204-3, 204-4 and 204-5), the gate-all-around (GAA) field-effect transistor devices 510 (including gate-all-around (GAA) field-effect transistor devices 510-1, 510-2, 510-3, 510-4) and a dielectric layer 230. In some embodiments, the semiconductor substrate 200 includes the active regions A1, A2, A3 and A4. In some embodiments, the material of the semiconductor substrate 200 includes Si, SiP, SiGe, SiC, SiPC, Ge, SOI-Si, SOI-SiGe, III-VI material, or a combination thereof. In some embodiments, the semiconductor substrate 200 is electrically floating.

The well regions 202 (including well regions 202-1, 202-2, 202-3 and 202-4) are arranged in the semiconductor substrate 200 along a direction D1 and extend along a direction D2 that is different from the direction D1. In addition, the well regions 202 are separated from each other by the well regions 204 (including well regions 204-1, 204-2, 204-3, 204-4 and 204-5) along the direction D1. In other words, the well regions 202-1, 202-2, 202-3 and 202-4 are disposed between the well regions 204-1, 204-2, 204-3, 204-4 and 204-5. It is noted that the numbers of the well regions 202 and 204 are merely examples and are not limited to the disclosed embodiments. In some embodiments, the well regions 202 and 204 may be well regions for the core devices formed therein. The well regions 202 and 204 may be also called low-voltage well regions 202 and 204. In some embodiments, the well regions 202 and 204 have opposite conductivity types. For example, the well regions 202 are N-type well regions 202, and the well regions 204 are P-type well regions 204. As shown in FIG. 3, the well regions 202-1, 202-2, 202-3, 202-4 and 202-5 have top surfaces 202-1T, 202-2T, 202-3T, 202-4T, 202-5T and bottom surfaces 202-1B, 202-2B, 202-3B, 202-4B, 202-5B. In some embodiments, the top surfaces 202-1T, 202-2T, 202-3T, 202-4T, 202-5T are aligned with the top surface 200T of the semiconductor substrate 200. In addition, the bottom surfaces 202-1B, 202-2B, 202-3B, 202-4B, 202-5B are aligned with the bottom surface 200B of the semiconductor substrate 200. In other words, the bottom surfaces 202-1B, 202-2B, 202-3B, 202-4B, 202-5B of the well regions 202-1, 202-2, 202-3, 202-4, 202-5 are exposed from the bottom surface 200B of the semiconductor substrate 200.

The gate-all-around (GAA) field-effect transistor devices 510 are formed over the well regions 202. In some embodiments, the field-effect transistor devices 510 include fin structures 220 (including fin structures 220-1, 220-2, 220-3, 220-4) and epitaxial source/drain features 240 (including source/drain features 240-1, 240-2, 240-3, 240-4). The fin structures 220 are formed protruding from the semiconductor substrate 200 in the well regions 202. In some embodiments, each of the fin structures 220 includes channel layers 212 and a gate structure 250 (including gate structure 250-1, 250-2, 250-3, 250-4) that is wrapped around the channel layers 212. In addition, the bottommost channel layer 212 is formed on the insulating layer 210 covering the semiconductor substrate 200.

In some embodiments, the fin structures 202-1, 202-2, 202-3, 202-4 extends along the direction D2. The fin structures 202-1, 202-2, 202-3, 202-4 may be formed by patterning a stack (not shown) of alternating channel layers 212 and sacrificial layers (not shown). In addition, trenches 224 are formed between the fin structures 202-1, 202-2, 202-3, 202-4 after performing the patterning process. Therefore, the fin structures 202-1, 202-2, 202-3, 202-4 are separated from each other. Each of the fin structures 202-1, 202-2, 202-3, 202-4 includes a base portion 220B and an upper portion (not shown). The base portion 220B is formed from the semiconductor substrate 200. The upper portion (not shown) is composed of the patterned stack (not shown) of alternating channel layers 212 and sacrificial layers (not shown) formed on the insulating layer 210 covering the semiconductor substrate 200. In some embodiments, the fin structures 202-1, 202-2, 202-3, 202-4 may also serve as active regions A1, A2, A3 and A4 to provide the gate-all-around (GAA) field-effect transistor devices 510-1, 510-2, 510-3, 510-4 formed thereon. In some embodiments, the active regions A1, A2, A3 and A4 are located on different fins. In some other embodiments, the active region A4 and any of the active regions A1, A2, A3 are different portions of the same fin. In some embodiments as shown in FIG. 2, three channel layers 212 are formed in the figures. In some other embodiments, the stack of alternating channel layers 212 and sacrificial layers may include more or fewer channel layers 212. For example, the stack of alternating channel layers 212 and sacrificial layers may include from two to ten channel layers 212, depending on the desired number of channel layers for forming gate-all-around (GAA) field-effect transistor devices 510-1, 510-2, 510-3, 510-4.

In some embodiments, the semiconductor structure 500 further includes isolation features 228 formed on sidewalls of the base portion 220B of each of the fin structures 220 before forming the gate structures 250. The isolation features 228 are formed around the base portion 220B of each of the fin structures 220. In addition, top surfaces 228T of the isolation features 228 may be lower than a top portion of the base portion 220B in the channel region of each of the fin structures 220. In some embodiments, the isolation feature 228 comprises silicon oxide, silicon nitride, silicon oxynitride (SiON), another suitable insulating material, or a combination thereof. In some embodiments, the isolation feature 228 is formed by performing a depositing process of an insulating material (not shown), a planarization process and a recessing process. The depositing process may be performed to form the insulating material (not shown) filling the trenches 224. The depositing process may comprise thermal growth, spin-on coating, chemical vapor deposition (CVD), high density plasma CVD (HDP-CVD), physical vapor deposition (PVD), atomic layer deposition (ALD), or any other applicable deposition processes. The planarization process may be performed so that a top surface of the insulating material (not shown) is level with a top surface of each of the fin structures 220. The planarization process may comprise chemical mechanical polishing (CMP) or any other applicable planarization processes. In addition, the recessing process may be performed to recess the insulating material to form the isolation features 228. The recessing process may comprise reactive ion etching (RIE), dry etching, wet etching, or any other applicable etching processes.

The epitaxial source/drain structures 240 of the gate-all-around (GAA) field-effect transistor devices 510 are formed in the source/drain recesses (not shown) in the fin structures 220. The epitaxial source/drain structures 240 are disposed on and connected to opposite sides of the channel layers 212 of the fin structures 220. In some embodiments, the epitaxial source/drain structures 240 comprise epitaxial semiconductor materials in-situ or ex-situ doped with an n-type dopant or a p-type dopant. In some embodiments, the epitaxial source/drain structures 240 may have a first conductivity type, and the well regions 202 may have a second conductivity type that is different from the first conductivity type. For example, the epitaxial source/drain structures 240 may comprise silicon-germanium (SiGe) doped with

P-type dopants such as boron, and the well regions 202 may be N-type well regions 202. For example, the epitaxial source/drain structures 240 may comprise silicon (Si) doped with N-type dopants such as phosphorous (P), and the well regions 202 may be P-type well regions 202. In addition, the semiconductor substrate 200 may have the first conductivity type such as P-type, or the second conductivity type such as N-type, depending on requirements. In some embodiments, the epitaxial source/drain structures 240 are epitaxially grown from the channel layers 212 by an epitaxial growth process includes molecular beam epitaxy (MBE), metal organic chemical vapor deposition (MOCVD), vapor phase epitaxy (VPE), or other applicable epitaxial growth processes.

In some embodiments, each of the gate structures 250 of the gate-all-around (GAA) field-effect transistor devices 510 includes a gate dielectric layer (not shown) wrapping the channel layers 212 and a gate electrode layer (not shown) formed on the gate dielectric layer in the channel region. Therefore, the gate electrode layers of the gate structures 250-1, 250-2, 250-3 and 250-4 (not shown) may be separated from the channel layers 212 and the base portion 202B of the fin structures 220-1, 220-2, 220-3 and 220-4 by the gate dielectric layers. In some embodiments, the gate dielectric layer comprises silicon oxide, silicon nitride, or high-k dielectric material, other applicable dielectric material or combinations thereof. In some embodiments, the gate dielectric layer is formed by chemical vapor deposition (CVD), physical vapor deposition, (PVD), atomic layer deposition (ALD) or other applicable deposition processes. In some embodiments, the gate electrode layer comprises conductive materials. In some embodiments, the gate electrode layer is formed by chemical vapor deposition (CVD), physical vapor deposition, (PVD), atomic layer deposition (ALD) or other applicable deposition processes.

The dielectric layer 230 may be formed covering sidewalls of the gate structures 250 and filling spaces (not shown) between the gate structures 250 and the epitaxial source/drain structures 240. In addition, the dielectric layer 230 may be in contact with the gate structures 250 and the epitaxial source/drain structures 240. In some embodiments, the dielectric layer 230 may be a single layer structure or a composite layer structure. For example, the dielectric layer 230 may include inner spacers and/or gate spacers. The inner spacers may be formed between and in contact with the channel layers 212 vertically adjacent to each other. The gate spacers may be formed on the topmost channel layer 212 of the fin structures 220. In some embodiments, the dielectric layer 230 comprises dielectric materials such as silicon oxide (SiO2), silicon nitride (SiN), silicon carbide (SiC), silicon oxynitride (SiON), silicon carbon nitride (SiCN), silicon oxide carbonitride (SiOCN), or a combination thereof. In some embodiments, the dielectric layer 230 may be formed by a deposition process and a subsequent etching back process. The deposition process may comprise chemical vapor deposition (CVD), flowable chemical vapor deposition, subatmospheric chemical vapor deposition (SACVD), physical vapor deposition (PVD), atomic layer deposition (ALD), or any other applicable deposition processes. The etching back process may comprise wet etching, dry etching or a combination thereof.

In some embodiments, the semiconductor structure 500 further includes a front-side interconnect structure 260 (shown in FIG. 3) formed over the gate-all-around (GAA) field-effect transistor devices 510 and the dielectric layer 230. The a front-side interconnect structure 260 may include an interlayer dielectric (ILD) layer 242, front-side gate contacts 254G1, 254G2, 254G3, 254G4, front-side source/drain contacts 254S1, 254S2, 254S3, 254S4, 254S5, interconnect features 264G1, 264S1, 264S2, 264S3, 264G4, 264S4, 264S5 and an intermetal dielectric (IMD) layer 262.

The interlayer dielectric (ILD) layer 242 of the front-side interconnect structure 260 (shown in FIG. 3) is formed covering the gate-all-around (GAA) field-effect transistor devices 510. In some embodiments, the ILD layer 242 comprises borophosphosilicate glass (BPSG), fused silica glass (FSG), phosphosilicate glass (PSG), boron doped silicon glass (BSG), tetraethylorthosilicate (TEOS) oxide, and/or other applicable dielectric materials In some embodiments, the ILD layer 242 is formed by chemical vapor deposition (CVD), physical vapor deposition, (PVD), atomic layer deposition (ALD) or other applicable deposition processes.

As shown in FIG. 3, the front-side gate contacts 254G1, 254G2, 254G3, 254G4 and front-side source/drain contacts 254S1, 254S2, 254S3, 254S4, 254S5 are formed over the dielectric layer 230 and passing through the ILD layer 242. The interconnect features 264G1, 264S1, 264S2, 264S3, 264G4, 264S4, 264S5 and the intermetal dielectric (IMD) layer 262 of the front-side interconnect structure 260 are formed on the interlayer dielectric (ILD) layer 242. The interconnect features 264G1, 264S2, 264S3 are formed in the intermetal dielectric (IMD) layer 262. In addition, the semiconductor structure 500 may further include back-side gate contact 274G1 and back-side source/drain contacts 274S1, 274S2 formed below the dielectric layer 230 and passing through the semiconductor substrate 200. In some embodiments, the front-side gate contacts 254G1, 254G2, 254G3, 254G4 and the front-side source/drain contacts 254S1, 254S2, 254S3, 254S4, 254S5, the back-side gate contact 274G1 and the back-side source/drain contacts 274S1, 274S2 include copper (Cu), tungsten (W), aluminum (Al), titanium (Ti), tantalum (Ta), cobalt (Co), and/or silicide. The front-side gate contacts 254G1, 254G2, 254G3, 254G4 and the front-side source/drain contacts 254S1, 254S2, 254S3, 254S4, 254S5, the back-side gate contact 274G1 and the back-side source/drain contacts 274S1, 274S2 are formed by a deposition process and a subsequent planarization process. In some embodiments, the deposition process may comprise chemical vapor deposition (CVD), plasma enhanced CVD (PECVD), physical vapor deposition, (PVD), atomic layer deposition (ALD) or other applicable deposition processes. In some embodiments, the planarization process comprises chemical mechanical polishing (CMP), etching back or a combination thereof.

In some embodiments, the gate-all-around (GAA) field-effect transistor device 510-1, 510-2 and 510-3 may be electrically connected to the external circuits (not shown) by the front-side gate contacts, the front-side source/drain contacts and the interconnect features of the front-side interconnect structure 260. For example, the front-side gate contacts 254G1, 254G2, 254G3 are electrically connected to the gate structures 250-1, 250-2 and 250-3 of the gate-all-around (GAA) field-effect transistor device 510-1, 510-2 and 510-3 on the fin structures 220-1, 220-2, 220-1 (on the active regions A1, A2, A3). The front-side source/drain contacts 254S1, 254S2, 254S3 of the front-side interconnect structure 260 are electrically connected to the epitaxial source/drain structures 240-1, 240-2 and 240-3 of the gate-all-around (GAA) field-effect transistor device 510-1, 510-2 and 510-3 on the fin structure 220-4 (on the active region A4).

As shown in FIGS. 1 and 3, the interconnect feature 264G1 may be electrically connected to the front-side gate contacts 254G1 of the gate-all-around (GAA) field-effect transistor devices 510-1 on the same fin structure 220-1. Therefore, the gate structures 250-1 of the gate-all-around (GAA) field-effect transistor devices 510-1 on the same fin structure 220-1 may be electrically connected to each other. The interconnect feature 264S1 may be electrically connected to the front-side source/drain contacts 254S1 of the gate-all-around (GAA) field-effect transistor device 510-1 on the same fin structure 220-1 and the front-side gate contacts 254G2 of the gate-all-around (GAA) field-effect transistor devices 510-2 on the same fin structure 220-2. Therefore, the epitaxial source/drain features 240-1 of the gate-all-around (GAA) field-effect transistor device 510-1 on the same fin structure 220-1 and the gate structures 250-2 of the gate-all-around (GAA) field-effect transistor devices 510-2 on the same fin structure 220-2 may be electrically connected to each other. In addition, the interconnect feature 264S2 may be electrically connected to the front-side source/drain contacts 254S2 of the gate-all-around (GAA) field-effect transistor devices 510-2 on the same fin structure 220-2 and the front-side gate contacts 254G3 of the gate-all-around (GAA) field-effect transistor devices 510-3 on the same fin structure 220-3. Therefore, the epitaxial source/drain features 240-2 of the gate-all-around (GAA) field-effect transistor device 510-2 on the same fin structure 220-2 and the gate structures 250-3 of the gate-all-around (GAA) field-effect transistor devices 510-3 on the same fin structure 220-3 may be electrically connected to each other. Furthermore, the interconnect feature 264S3 may be electrically connected to the front-side source/drain contacts 254S3 of the gate-all-around (GAA) field-effect transistor devices 510-3 on the same fin structure 220-3. Therefore, the epitaxial source/drain features 240-3 of the gate-all-around (GAA) field-effect transistor device 510-3 on the same fin structure 220-3 may be electrically connected to each other.

In some embodiments, the interconnect feature 264G1 may be electrically connected to a power supply terminal VCC, and the interconnect feature 264S3 may be electrically connected to a ground terminal GND. Therefore, the gate structures 250-1 of the gate-all-around (GAA) field-effect transistor devices 510-1 on the same fin structure 220-1 may be electrically connected to the power supply terminal VCC by the front-side gate contacts 254G1 and the interconnect feature 264G1. The epitaxial source/drain features 240-1 of the gate-all-around (GAA) field-effect transistor device 510-1 on the same fin structure 220-1 may be electrically connected to the gate structures 250-2 of the gate-all-around (GAA) field-effect transistor devices 510-2 on the same fin structure 220-2 by the front-side source/drain contacts 254S1, the front-side gate contacts 254G2 and the interconnect feature 264S1. In addition, the epitaxial source/drain features 240-2 of the gate-all-around (GAA) field-effect transistor device 510-2 on the same fin structure 220-2 may be electrically connected to the gate structures 250-3 of the gate-all-around (GAA) field-effect transistor devices 510-3 on the same fin structure 220-3 by the front-side source/drain contacts 254S2, the front-side gate contacts 254G3 and the interconnect feature 264S2. Furthermore, the epitaxial source/drain features 240-3 of the gate-all-around (GAA) field-effect transistor device 510-3 on the same fin structure 220-3 may be electrically connected to the ground terminal GND by the front-side source/drain contacts 254S3 and the interconnect feature 264S3. Alternatively, the interconnect feature 264G1 may be electrically connected to the ground terminal GND, and the interconnect feature 264S3 may be electrically connected to the power supply terminal VCC.

In the gate-all-around (GAA) field-effect transistor devices 510-1, 510-2 and 510-3, the gate structures 250-1 and the epitaxial source/drain features 240-1 and a portion of the dielectric layer 230 between the gate structures 250-1 and the epitaxial source/drain features 240-1 may form a capacitor C1. The gate structures 250-2 and the epitaxial source/drain features 240-2 and a portion of the dielectric layer 230 between the gate structures 250-2 and the epitaxial source/drain features 240-2 may form a capacitor C2. The gate structures 250-3 and the epitaxial source/drain features 240-3 and a portion of the dielectric layer 230 between the gate structures 250-3 and the epitaxial source/drain features 240-3 may form a capacitor C3. In some embodiments, the capacitors C1, C2 and C3 are connected in series. The serious connected capacitors C1, C2 and C3 may have a cas-code capacitor structure.

Since IO devices are not provided in the current gate-all-around (GAA) platform, the series connected capacitors C1, C2 and C3 formed in the active regions A1, A2, A3 for core devices operated in low voltage (at the voltage level below 1.2V) may provide as a capacitor for IO device operated as high voltages (at a voltage level between 1.2 and 2.5V). For example, if each of the capacitors C1, C2 and C3 may be rated for 0.6V. An IO capacitor rated for 1.2V may be formed by connecting two capacitors C1, C2 in series. Alternatively, an IO capacitor rated for 1.8V may be formed by connecting three capacitors C1, C2, C3 in series, and so on. The more core capacitors formed from the gate-all-around (GAA) field-effect transistor devices 510 are connected in series, the higher voltage rating of the IO capacitor is obtained. In addition, the bottom surfaces of the well regions 202 are aligned to the bottom surface 200B of the semiconductor substrate 200, and the semiconductor substrate 200 is electrically floating. Therefore, the capacitors C1, C2 and C3 may not share the common bulk voltage. The IO capacitors composed of the core capacitors and having higher voltage rating (higher than the breakdown voltage of the well regions 200) are available.

In some embodiments, the gate-all-around (GAA) field-effect transistor devices 510-4 (including gate-all-around (GAA) field-effect transistor devices 510-4A and 510-4B on the fin structure 220-4 (on the active region A4) are electrically connected to the external circuit (not shown) by the front-side gate contacts and the front-side source/drain contacts, the back-side gate contacts and the back-side source/drain contacts. For example, the front-side gate contact 254G4 are electrically connected to the gate structures 250-4 of the gate-all-around (GAA) field-effect transistor device 510-4A. The front-side source/drain contacts 254S4, 254S5 of the front-side interconnect structure 260 are electrically connected to the epitaxial source/drain structures 240-4 of the gate-all-around (GAA) field-effect transistor device 510-4B. In addition, the back-side source/drain contacts 274S1 and 274S2 are electrically connected to the epitaxial source/drain features 240-4 of the gate-all-around (GAA) field-effect transistor device 510-4A. Furthermore, the back-side gate contact 274G1 is electrically connected to the gate structure 250-4 of the gate-all-around (GAA) field-effect transistor device 510-4B. In some other embodiments, the gate structures 250-4 and the epitaxial source/drain structures 240-4 of the gate-all-around (GAA) field-effect transistor device 510-4 may be electrically connected to the front-side gate contact and the back-side source/drain contacts without using the front-side gate contacts or the front-side source/drain contacts. In some embodiments in which the gate-all-around (GAA) field-effect transistor devices 510-4 are form on the active region A1, A2 or A3, the epitaxial source/drain features 240-4 of the gate-all-around (GAA) field-effect transistor devices 510-4 are not used as the epitaxial source/drain features 240-1, 240-2 or 240-3.

As shown in FIGS. 1 and 3, the interconnect feature 264G4 may be electrically connected to the front-side gate contacts 254G4 of the gate-all-around (GAA) field-effect transistor devices 510-4A. The interconnect features 264S4, 264S5 may be electrically connected to the front-side source/drain contacts 254S4, 254S5 of the gate-all-around (GAA) field-effect transistor devices 510-4B.

In some embodiments, the back-side gate contact 274G4 and the back-side source/drain contacts 274S1 and 274S2 may be electrically connected to a power circuit (not shown). The power circuit may serve as a back-side power mesh for the semiconductor structure 500.

In the gate-all-around (GAA) field-effect transistor devices 510-4, the gate structures 250-4 and the two epitaxial source/drain features 240-4 of the gate-all-around (GAA) field-effect transistor device 510-4A (or the gate-all-around (GAA) field-effect transistor device 510-4B) are electrically connected to different contacts (including the front-side gate contact 254G4 and the front-side source/drain contacts 254S4, 254S5, the back-side gate contact 274G1 and the back-side source/drain contacts 274S1, 274S2). Therefore, the gate-all-around (GAA) field-effect transistor devices 510-4 are operated as field-effect transistors.

Embodiments provide a semiconductor structure applied in the back-side power technology. The semiconductor structure includes cas-code capacitors formed from the gate-all-around (GAA) structures. The semiconductor structure includes a semiconductor substrate, a first well region, a second well region, a first gate-all-around (GAA) field-effect transistor device and a second gate-all-around (GAA) field-effect transistor device. In the semiconductor structure, top and bottom surfaces of the first and second well regions are aligned with the top and bottom surfaces of the semiconductor substrate. In some embodiments, a first gate structure of the first gate-all-around (GAA) field-effect transistor device is electrically connected to a power supply terminal, In addition, the first epitaxial source/drain features of the first gate-all-around (GAA) field-effect transistor device are electrically connected to a second gate structure of the second gate-all-around (GAA) field-effect transistor device. Furthermore, second epitaxial source/drain features of the second gate-all-around (GAA) field-effect transistor device are electrically connected to a ground terminal. The semiconductor structure further includes a first dielectric layer covering the first and second gate structures. Therefore, the first gate structure, the first epitaxial source/drain features and a first portion of the first dielectric layer between the first gate structure and first epitaxial source/drain features form a first capacitor. The second gate structure and the second epitaxial source/drain features and a second portion of the first dielectric layer between the second gate structure and second epitaxial source/drain features form a second capacitor in series connected to the first capacitor. The series connected capacitors may be form as a cas-code capacitor having the increased withstand voltage. In addition, the bottom surfaces of the first and second well regions are exposed from the bottom surface of the semiconductor substrate, and the semiconductor substrate is electrically floating. The series connected capacitors may not share the bulk voltage. Therefore, the capacitors for core devices having lower withstand voltage may be connected in series in order to form the cas-code capacitor for IO devices having higher withstand voltage. In some embodiments, the semiconductor structure may further include a third gate-all-around (GAA) field-effect transistor device over a third well region in the semiconductor substrate. Terminals of the third gate-all-around (GAA) field-effect transistor device may be electrically connected to different contacts (including front-side contacts and/or back-side contacts) and used as a field-effect transistor device. At least one terminal of the third gate-all-around (GAA) field-effect transistor device may be electrically connected to a back-side contact passing through the semiconductor substrate. For example, a third gate structure of the third gate-all-around (GAA) field-effect transistor device may be electrically connected to a third back-side gate contact. For example, one of third epitaxial source/drain features of the third gate-all-around (GAA) field-effect transistor device may be electrically connected to third back-side source/drain contact.

While the invention has been described by way of example and in terms of the preferred embodiments, it should be understood that the invention is not limited to the disclosed embodiments. On the contrary. it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a semiconductor substrate having a top surface and a bottom surface;
a first well region and a second well region arranged in the semiconductor substrate and separated from each other, wherein top and bottom surfaces of the first and second well regions are aligned with the top and bottom surfaces of the semiconductor substrate;
a first gate-all-around (GAA) field-effect transistor device formed over the first well region, wherein the first GAA field-effect transistor device comprises:
a first gate structure; and
first epitaxial source/drain features disposed on opposite sides of the first gate structure; and
a second gate-all-around (GAA) field-effect transistor device formed over the second well region, wherein the second GAA field-effect transistor device comprises:
a second gate structure; and
second epitaxial source/drain features disposed on opposite sides of the second gate structure;
wherein the first gate structure is electrically connected to a power supply terminal,
wherein the first epitaxial source/drain features are electrically connected to the second gate structure, and
wherein the second epitaxial source/drain features are electrically connected to a ground terminal.

2. The semiconductor structure as claimed in claim 1, wherein the first epitaxial source/drain features are electrically connected to each other.

3. The semiconductor structure as claimed in claim 1, wherein the second epitaxial source/drain features are electrically connected to each other.

4. The semiconductor structure as claimed in claim 1, further comprising:
a first dielectric layer covering the first and second gate structures, wherein the first gate structure and the first epitaxial source/drain features and a first portion of the first dielectric layer between the first gate structure and first epitaxial source/drain features form a first capacitor.

5. The semiconductor structure as claimed in claim 4, wherein the second gate structure and the second epitaxial source/drain features and a second portion of the first dielectric layer between the second gate structure and second epitaxial source/drain features form a second capacitor.

6. The semiconductor structure as claimed in claim 5, wherein the first capacitor and the second capacitor are connected in series.

7. The semiconductor structure as claimed in claim 4, further comprising:
a second dielectric layer covering the first and second GAA field-effect transistor devices;
a first front-side gate contact passing through the second dielectric layer and electrically connected to the first gate structure; and
first front-side source/drain contacts passing through the second dielectric layer and electrically connected to the first epitaxial source/drain features.

8. The semiconductor structure as claimed in claim 7, further comprising:
a second front-side gate contact passing through the second dielectric layer and electrically connected to the second gate structure; and
second front-side source/drain contacts passing through the second dielectric layer and electrically connected to the second epitaxial source/drain features.

9. The semiconductor structure as claimed in claim 1, wherein the semiconductor substrate is electrically floating.

10. The semiconductor structure as claimed in claim 1, wherein the first and second source/drain epitaxial features have a first conductivity type, and wherein the first and second well regions have a second conductivity type that is different from the first conductivity type.

11. The semiconductor structure as claimed in claim 10, wherein the semiconductor substrate has the first conductivity type.

12. The semiconductor structure as claimed in claim 4, further comprising:
a third well region arranged in the semiconductor substrate, wherein top and bottom surfaces of the third well region are aligned with the top and bottom surfaces of the substrate;
a third gate-all-around (GAA) field-effect transistor device formed over the third well region, wherein the third GAA field-effect transistor device comprises:
a third gate structure; and
third epitaxial source/drain features disposed on opposite sides of the third gate structure; and
a third back-side gate contact passing through the semiconductor substrate and electrically connected to the third gate structure.

13. The semiconductor structure as claimed in claim 12, further comprising:
a third back-side source/drain contact passing through the semiconductor substrate and electrically connected to one of the third epitaxial source/drain features.

14. The semiconductor structure as claimed in claim 9, wherein the third epitaxial source/drain features of the third GAA field-effect transistor device is not used as the first epitaxial source/drain features or the second epitaxial source/drain features.

15. A semiconductor structure, comprising:
a semiconductor substrate having a top surface and a bottom surface;
a first well region and a second well region arranged in the semiconductor substrate, wherein bottom surfaces of the first and second well regions are exposed from a bottom surface of the semiconductor substrate;
a first gate-all-around (GAA) field-effect transistor device formed over the first well region, wherein the first GAA field-effect transistor device comprises:
a first fin structure protruding from the semiconductor substrate, wherein the first fin structure comprises first channel layers and a first gate structure that is wrapped around the first channel layer; and
first epitaxial source/drain features connected to opposite sides of the first channel layers;
a second gate-all-around (GAA) field-effect transistor device formed over the second well region, wherein the second GAA field-effect transistor device comprises:
a second fin structure protruding from the semiconductor substrate, wherein the second fin structure comprises second channel layers and a second gate structure that is wrapped around the second channel layer; and
second epitaxial source/drain features disposed on opposite sides of the second channel layers; and
a first dielectric layer covering the first and second gate structures;
wherein the first epitaxial source/drain features are electrically connected to the second gate structure, and
wherein the first gate structure, the first epitaxial source/drain features, and a first portion of the first dielectric layer between the first gate structure and first epitaxial source/drain features form a first capacitor.

16. The semiconductor structure as claimed in claim 15, wherein the first fin structure and the second fin structure are separated from each other.

17. The semiconductor structure as claimed in claim 15, wherein the second epitaxial source/drain features are electrically connected to each other, and wherein the second gate structure and the second epitaxial source/drain features and a second portion of the first dielectric layer between the second gate structure and second epitaxial source/drain features form a second capacitor.

18. The semiconductor structure as claimed in claim 17, wherein the first capacitor and the second capacitor are connected in series.

19. The semiconductor structure as claimed in claim 17, wherein the first gate structure is electrically connected to a power supply terminal, and wherein the second epitaxial source/drain features are electrically connected to a ground terminal.

20. The semiconductor structure as claimed in claim 15, further comprising:
a second dielectric layer covering the first and second GAA field-effect transistor devices;
a first front-side gate contact passing through the second dielectric layer and electrically connected to the first gate structure of the first GAA field-effect transistor device;
first front-side source/drain contacts passing through the second dielectric layer and electrically connected to the first epitaxial source/drain features of the first GAA field-effect transistor device;
a second front-side gate contact passing through the second dielectric layer and electrically connected to the second gate structure of the second GAA field-effect transistor device; and
second front-side source/drain contacts passing through the second dielectric layer and electrically connected to the second epitaxial source/drain features of the second GAA field-effect transistor device.

21. The semiconductor structure as claimed in claim 15, wherein the semiconductor substrate is electrically floating.

22. The semiconductor structure as claimed in claim 15, wherein the first and second source/drain epitaxial features have a first conductivity type, and wherein the first and second well regions have a second conductivity type that is different from the first conductivity type.

23. The semiconductor structure as claimed in claim 22, wherein the semiconductor substrate has the first conductivity type.

24. The semiconductor structure as claimed in claim 15, further comprising:
a third well region arranged in the semiconductor substrate, wherein top and bottom surfaces of the third well region are aligned with the top and bottom surfaces of the substrate;
a third gate-all-around (GAA) field-effect transistor device formed over the third well region, wherein the third GAA field-effect transistor device comprises:
a third fin structure protruding from the semiconductor substrate, wherein the third fin structure comprises third channel layers and a third gate structure that is wrapped around the third channel layer; and
third epitaxial source/drain features disposed on opposite sides of the third channel layers; and
a third back-side gate contact passing through the semiconductor substrate and electrically connected to the third gate structure.

25. The semiconductor structure as claimed in claim 24, further comprising:
a third back-side source/drain contact passing through the semiconductor substrate and electrically connected to one of the third epitaxial source/drain features.

26. The semiconductor structure as claimed in claim 24, wherein the third epitaxial source/drain features of the third GAA field-effect transistor device are not used as the first, second. third or fourth epitaxial source/drain feature.
